(19) United States
(12) Patent Application Publication
(10) Pub. No.: US 2024/0145504 A1
(43) Pub. Date: May 2, 2024

(54) IMPROVED SEALS FOR SEMICONDUCTOR DEVICES WITH SINGLE-PHOTON AVALANCHE DIODE PIXELS

(71) Applicant: SEMICONDUCTOR COMPONENTS INDUSTRIES, LLC, Phoenix, AZ (US)

(72) Inventors: Jeffrey Peter GAMBINO, Gresham, OR (US); Rick Carlton JEROME, Washougal, WA (US); David T. PRICE, Gresham, OR (US); Michael Gerard KEYES, Dromcollogher (IE); Anne DEIGNAN, Limerick (IE)

(73) Assignee: SEMICONDUCTOR COMPONENTS INDUSTRIES, LLC, Phoenix, AZ (US)

(21) Appl. No.: 18/051,600

(22) Filed: Nov. 1, 2022

(51) Int. Cl. H01L 27/146

(52) U.S. Cl. CPC H01L 27/14618; H01L 27/14636; H01L 27/1464; H01L 27/14643

(57) ABSTRACT

A semiconductor device may include a plurality of single-photon avalanche diode (SPAD) pixels. The semiconductor device may be a backside device having a substrate at the backside, dielectric layers on the substrate, metal layers interleaved with the dielectric layers, and a through silicon via (TSV) formed in the backside through the substrate and the dielectric layers. TSV seal rings may be formed around the TSV to protect the semiconductor device from moisture and/or water ingress. The TSV seal rings may be coupled to a high-voltage cathode bond pad and be coupled to offset portions of one of the metal layers to reduce leakage and/or parasitic effects due to the voltage difference between the cathode and the substrate. The TSV seal rings may also be merged with die seal rings at the edge of the substrate.

### BACKGROUND

This relates generally to imaging systems and, more particularly, to imaging systems that include single-photon avalanche diodes (SPADs) for single photon detection.

Modern electronic devices such as cellular telephones, cameras, and computers often use digital image sensors. Image sensors (sometimes referred to as imagers) may be formed from a two-dimensional array of image sensing pixels. Each pixel may include a photosensitive element (such as a photodiode) that receives incident photons (light) and converts the photons into electrical signals. Each pixel may also include a microlens that overlaps and focuses light onto the photosensitive element.

Conventional image sensors with backside-illuminated pixels may suffer from limited functionality in a variety of ways. For example, some conventional image sensors may not be able to determine the distance from the image sensor to the objects that are being imaged. Conventional image sensors may also have lower than desired image quality and resolution.

To improve sensitivity to incident light, single-photon avalanche diodes (SPADs) may sometimes be used in imaging systems. However, SPADs may require larger photosensitive regions than conventional image sensors and may require higher voltages, both of which may leave SPADs susceptible to moisture and/or water ingress.

It is within this context that the embodiments herein arise.

### BRIEF DESCRIPTION OF THE DRAWINGS

FIG. 1 is a circuit diagram showing an illustrative single-photon avalanche diode pixel in accordance with some embodiments.

FIG. 2 is a diagram of an illustrative silicon photomultiplier in accordance with some embodiments.

FIG. 3 is a schematic diagram of an illustrative imaging system with a SPAD-based semiconductor device in accordance with some embodiments.

FIG. 4 is a diagram of an illustrative pixel array and associated readout circuitry for reading out image signals in a SPAD-based semiconductor device in accordance with some embodiments.

FIG. 5 is a cross-sectional side view of an illustrative semiconductor device having a through silicon via (TSV) and multiple TSV seal rings coupled between two metal layers, including a cathode bond pad, in accordance with some embodiments.

FIG. 6 is a cross-sectional side view of an illustrative semiconductor device having a TSV and multiple TSV seal rings coupled between two metal layers, including a cathode bond pad, and merged with a die seal in accordance with some embodiments.

FIG. 7 is a cross-sectional side view of an illustrative semiconductor device having a TSV and multiple TSV seal rings coupled between two metal layers, including an anode bond pad, in accordance with some embodiments.

FIG. 8 is a cross-sectional side view of an illustrative semiconductor device having a TSV and multiple TSV seal rings coupled between two metal layers, including an anode bond pad, and merged with a die seal in accordance with some embodiments.

FIG. 9 is a cross-sectional side view of an illustrative semiconductor device having a TSV and multiple TSV seal rings coupled between three metal layers, including a cathode bond pad, in accordance with some embodiments.

FIG. 10 is a cross-sectional side view of an illustrative semiconductor device having a TSV and multiple TSV seal rings coupled between three metal layers, including a cathode bond pad, and merged with a die seal in accordance with some embodiments.

FIG. 11 is a cross-sectional side view of an illustrative semiconductor device having a TSV and multiple TSV seal rings coupled between three metal layers, including two TSV seal rings within the same layer, and merged with a die seal in accordance with some embodiments.

FIG. 12 is a cross-sectional side view of an illustrative semiconductor device having a TSV and multiple TSV seal rings coupled between three metal layers, including an anode bond pad, and merged with a die seal in accordance with some embodiments.

### DETAILED DESCRIPTION

Embodiments of the present technology relate to systems that include single-photon avalanche diodes (SPADs).

Some imaging systems include image sensors that sense light by converting impinging photons into electrons or holes that are integrated (collected) in pixel photodiodes within the sensor array. After completion of an integration cycle, collected charge is converted into a voltage, which is supplied to the output terminals of the sensor. In complementary metal-oxide semiconductor (CMOS) image sensors, the charge to voltage conversion is accomplished directly in the pixels themselves and the analog pixel voltage is transferred to the output terminals through various pixel addressing and scanning schemes. The analog pixel voltage can also be later converted on-chip to a digital equivalent and processed in various ways in the digital domain.

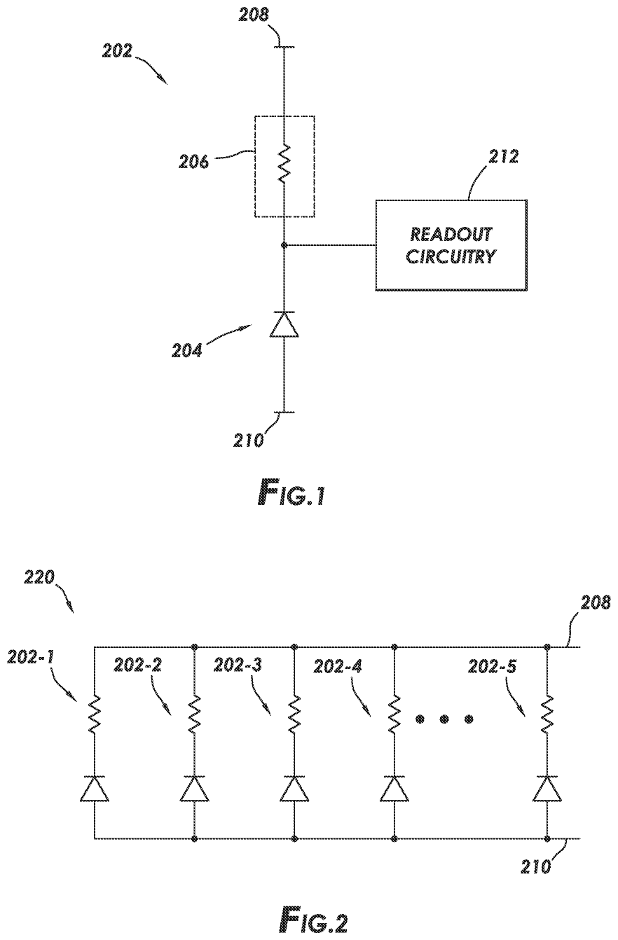

In single-photon avalanche diode (SPAD) devices (such as the ones described in connection with FIGS. 1-4), on the other hand, the photon detection principle is different. The light sensing diode is biased slightly above its breakdown point and when an incident photon generates an electron or hole, this carrier initiates an avalanche breakdown with additional carriers being generated. The avalanche multiplication may produce a current signal that can be detected by readout circuitry associated with the SPAD.

Because SPAD devices detect a single photon, SPAD pixels generally need to be larger than conventional pixels and also require additional voltage. As a result, SPAD devices may be more susceptible to ingress of moisture and water, particularly into through silicon vias (TSVs) within the SPAD devices.

FIG. 1 is a circuit diagram of an illustrative SPAD device 202. As shown in FIG. 1, SPAD device 202 includes a SPAD 204 that is coupled in series with quenching circuitry 206 between a first supply voltage terminal 208, which may be a ground power supply voltage terminal, and a second supply voltage terminal 210, which may be a positive power supply voltage terminal. During operation of SPAD device 202, supply voltage terminals 208 and 210 may be used to bias SPAD 204 to a voltage that is higher than the breakdown voltage. Breakdown voltage is the largest reverse voltage that can be applied without causing an exponential increase in the leakage current in the diode. When SPAD 204 is biased above the breakdown voltage in this manner, absorption of a single-photon can trigger a short-duration but relatively large avalanche current through impact ionization.

Quenching circuitry 206 (sometimes referred to as quenching element 206 herein) may be used to lower the bias voltage of SPAD 204 below the level of the breakdown voltage. Lowering the bias voltage of SPAD 204 below the breakdown voltage stops the avalanche process and corresponding avalanche current. There are numerous ways to form quenching circuitry 206. Quenching circuitry 206 may be passive quenching circuitry or active quenching circuitry. Passive quenching circuitry may, without external control or monitoring, automatically quench the avalanche current once initiated. For example, FIG. 1 shows an example where a resistor is used to form quenching circuitry 206, which is shown as passive quenching circuitry. After the avalanche is initiated, the resulting current rapidly discharges the capacity of the device, lowering the voltage at the SPAD to near to the breakdown voltage. The resistance associated with the resistor in quenching circuitry 206 may result in the final current being lower than required to sustain itself. The SPAD may then be reset to above the breakdown voltage to enable detection of another photon.

The example of passive quenching circuitry is merely illustrative. Active quenching circuitry may also be used in SPAD device 202. Active quenching circuitry may reduce the time it takes for SPAD device 202 to be reset. This may allow SPAD device 202 to detect incident light at a faster rate than when passive quenching circuitry is used, improving the dynamic range of the SPAD device. Active quenching circuitry may modulate the SPAD quench resistance. For example, before a photon is detected, quench resistance is set high and then once a photon is detected and the avalanche is quenched, quench resistance is minimized to reduce recovery time.

SPAD device 202 may also include readout circuitry 212. There are numerous ways to form readout circuitry 212 to obtain information from SPAD device 202. Readout circuitry 212 may include a pulse counting circuit that counts arriving photons. Alternatively or additionally, readout circuitry 212 may include time-of-flight circuitry that is used to measure photon time-of-flight (ToF). The photon time-of-flight information may be used to perform depth sensing.

In one example, photons may be counted by an analog counter to form the light intensity signal as a corresponding pixel voltage. The ToF signal may be obtained by also converting the time of photon flight to a voltage. The example of an analog pulse counting circuit being included in readout circuitry 212 is merely illustrative. If desired, readout circuitry 212 may include digital pulse counting circuits. Readout circuitry 212 may also include amplification circuitry, if desired.

The example in FIG. 1 of readout circuitry 212 being coupled to a node between diode 204 and quenching circuitry 206 is merely illustrative. Readout circuitry 212 may be coupled to any desired portion of the SPAD device. In some cases, quenching circuitry 206 may be considered integral with readout circuitry 212.

Because SPAD devices can detect a single incident photon, the SPAD devices are effective at imaging scenes with low light levels. Each SPAD may detect how many photons are received within a given period of time, such as by using readout circuitry that includes a counting circuit. However, as discussed above, each time a photon is received and an avalanche current initiated, the SPAD device must be quenched and reset before being ready to detect another photon. As incident light levels increase, the reset time becomes limiting to the dynamic range of the SPAD device. In particular, once incident light levels exceed a given level, the SPAD device is triggered immediately upon being reset.

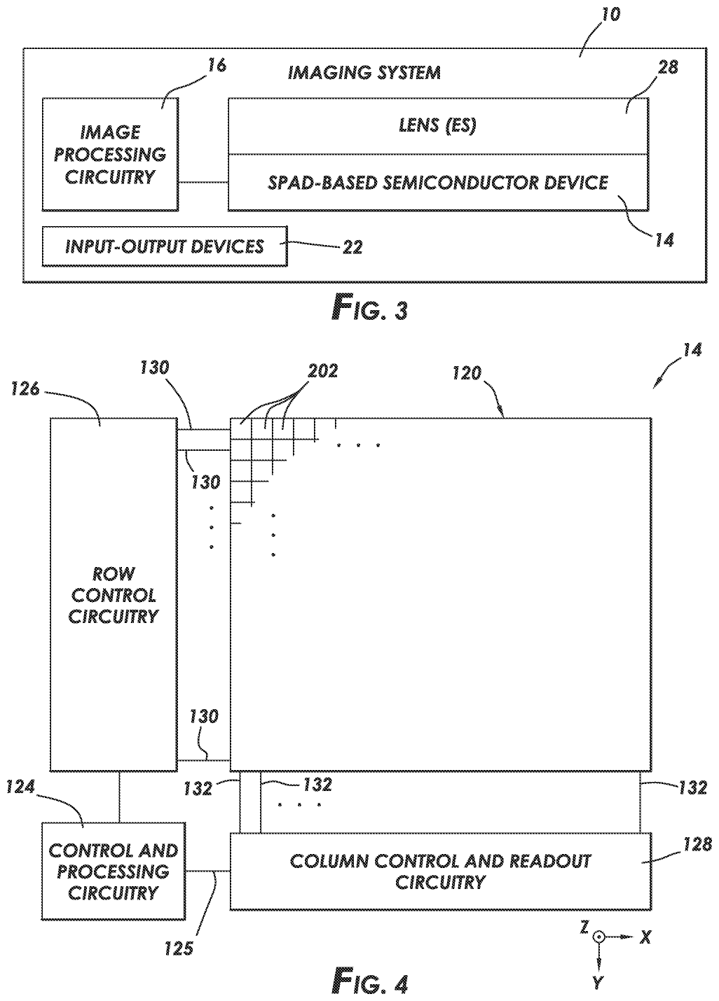

Multiple SPAD devices may be grouped together to increase dynamic range. FIG. 2 is a circuit diagram of an illustrative group 220 of SPAD devices 202. The group of SPAD devices may be referred to as a silicon photomultiplier (SiPM). As shown in FIG. 2, silicon photomultiplier 220 may include multiple SPAD devices that are coupled in parallel between first supply voltage terminal 208 and second supply voltage terminal 210. FIG. 2 shows N SPAD devices 202 coupled in parallel. In particular, silicon photomultiplier 220 may include SPAD device 202-1, SPAD device 202-2, SPAD device 202-3, SPAD device 202-4, . . . , SPAD device 202-N. More than two SPAD devices, more than ten SPAD devices, more than one hundred SPAD devices, or more than one thousand SPAD devices may be included in a given silicon photomultiplier.

Herein, each SPAD device may be referred to as a SPAD pixel 202. Although not shown explicitly in FIG. 2, readout circuitry for the silicon photomultiplier may measure the combined output current from all of SPAD pixels in the silicon photomultiplier. In this way, the dynamic range of an imaging system including the SPAD pixels may be increased. Each SPAD pixel is not guaranteed to have an avalanche current triggered when an incident photon is received, but each SPAD pixel may have an associated probability of an avalanche current being triggered when an incident photon is received. There is a first probability of an electron being created when a photon reaches the diode and then a second probability of the electron triggering an avalanche current. The total probability of a photon triggering an avalanche current may be referred to as the SPAD's photon-detection efficiency (PDE). Grouping multiple SPAD pixels together in the silicon photomultiplier therefore allows for a more accurate measurement of the incoming incident light. For example, if a single SPAD pixel has a PDE of 50% and receives one photon during a time period, there is a 50% chance the photon will not be detected. With the silicon photomultiplier 220 of FIG. 2, chances are that two of the four SPAD pixels will detect the photon, thus improving the provided image data for the time period.

The example of a plurality of SPAD pixels having a common output in a silicon photomultiplier is merely illustrative. In the case of an imaging system including a silicon photomultiplier having a common output for all of the SPAD pixels, the imaging system may not have any resolution in imaging a scene and the silicon photomultiplier may detect photon flux at a single point. It may be desirable to use SPAD pixels to obtain image data across an array to allow a higher resolution reproduction of the imaged scene. In cases such as these, SPAD pixels in a single imaging system may have per-pixel readout capabilities. Alternatively, an array of silicon photomultipliers, each including more than one SPAD pixel, may be included in the imaging system. The outputs from each pixel or from each silicon photomultiplier may be used to generate image data for an imaged scene. The array may be capable of independent detection, whether using a single SPAD pixel or a plurality of SPAD pixels in a silicon photomultiplier, in a line array. The line array may have a single row and multiple columns, may have a single column and multiple rows, or may have more than ten, more than one hundred, or more than one thousand rows and/or columns.

While there are a number of possible use cases for SPAD pixels as discussed above, the underlying technology used to detect incident light is the same. All of the aforementioned examples of devices that use SPAD pixels may collectively be referred to as SPAD-based semiconductor devices (also referred to as semiconductor devices herein). A silicon photomultiplier with a plurality of SPAD pixels having a common output may be referred to as a SPAD-based semiconductor device or a semiconductor device. An array of SPAD pixels with per-pixel readout capabilities may be referred to as a SPAD-based semiconductor device or a semiconductor device. An array of silicon photomultipliers with per-silicon-photomultiplier readout capabilities may be referred to as a SPAD-based semiconductor device or a semiconductor device.

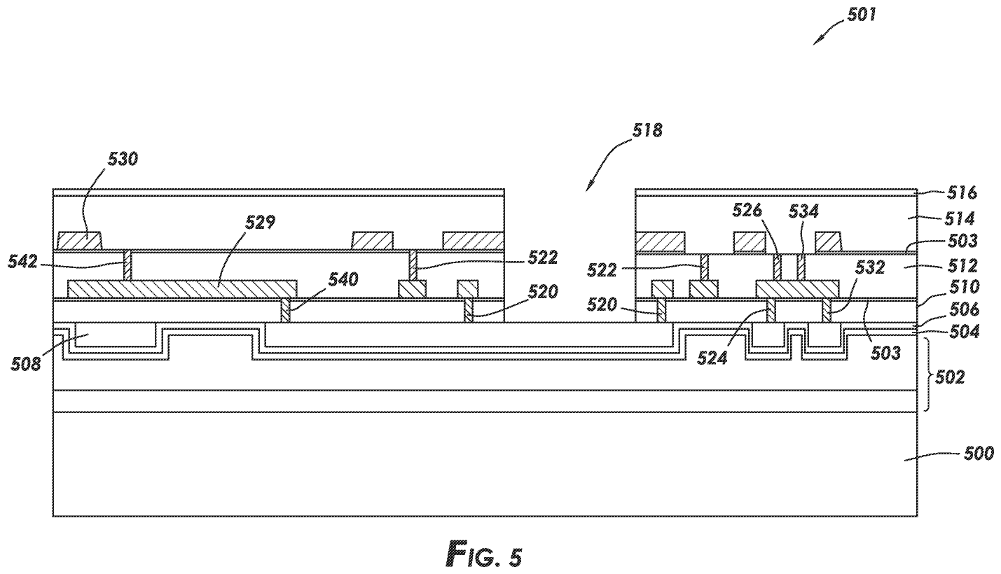

An imaging system 10 with a SPAD-based semiconductor device is shown in FIG. 3. Imaging system 10 may be an electronic device such as a digital camera, a computer, a cellular telephone, a medical device, or other electronic device. Imaging system 10 may be an imaging system on a vehicle (sometimes referred to as vehicular imaging system). Imaging system 10 may be used for LIDAR applications.

Imaging system 10 may include one or more SPAD-based semiconductor devices 14 (sometimes referred to as semiconductor devices 14, devices 14, SPAD-based image sensors 14, or image sensors 14). One or more lenses 28 may optionally cover each semiconductor device 14. During operation, lenses 28 (sometimes referred to as optics 28) may focus light onto SPAD-based semiconductor device 14. SPAD-based semiconductor device 14 may include SPAD pixels that convert the light into digital data. The SPAD-based semiconductor device may have any number of SPAD pixels, such as hundreds, thousands, or millions of SPAD pixels.

The SPAD-based semiconductor device 14 may optionally include additional circuitry such as bias circuitry, such as source follower load circuits, sample and hold circuitry, correlated double sampling (CDS) circuitry, amplifier circuitry, analog-to-digital (ADC) converter circuitry, data output circuitry, memory, such as buffer circuitry, address circuitry, and/or other suitable circuitry.

Image data from semiconductor device 14 may be provided to image processing circuitry 16. Image processing circuitry 16 may be used to perform image processing functions such as automatic focusing functions, depth sensing, data formatting, adjusting white balance and exposure, implementing video image stabilization, face detection, etc. For example, during automatic focusing operations, image processing circuitry 16 may process data gathered by the SPAD pixels to determine the magnitude and direction of lens movement, such as the movement of lens 28, needed to bring an object of interest into focus. Image processing circuitry 16 may process data gathered by the SPAD pixels to determine a depth map of the scene.

Imaging system 10 may provide a user with numerous high-level functions. In a computer or advanced cellular telephone, for example, a user may be provided with the ability to run user applications. To implement these functions, the imaging system may include input-output devices 22, such as keypads, buttons, input-output ports, joysticks, and displays. Additional storage and processing circuitry such as volatile and nonvolatile memory, which may include random-access memory, flash memory, hard drives, and/or solid state drives; microprocessors; microcontrollers; digital signal processors; application specific integrated circuits; and/or other processing circuits may also be included in the imaging system.

Input-output devices 22 may include output devices that work in combination with the SPAD-based semiconductor device. For example, a light-emitting component may be included in the imaging system to emit light, such as infrared light or light of any other desired wavelength. Semiconductor device 14 may measure the reflection of the light off of an object to measure distance to the object in a LIDAR (light detection and ranging) scheme.

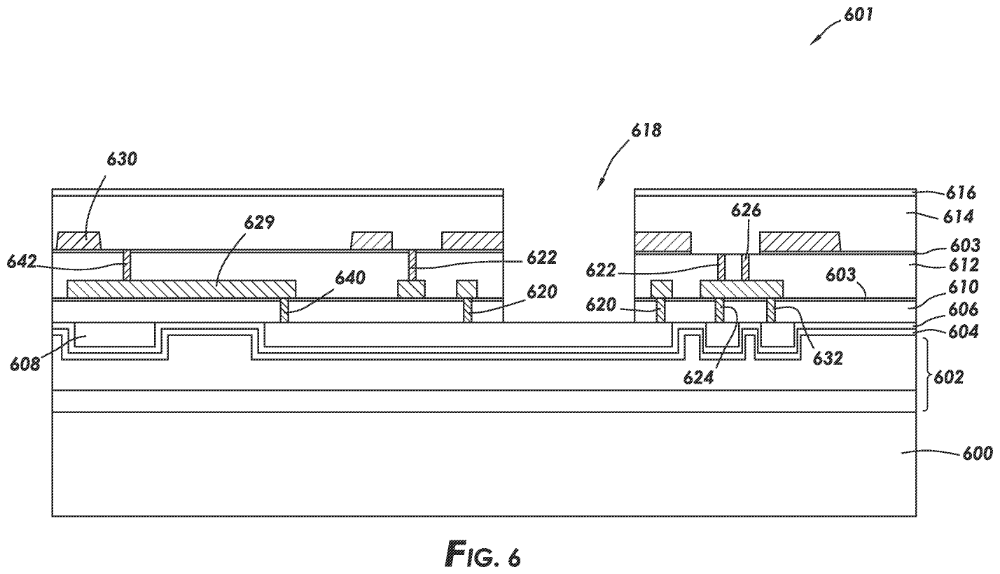

FIG. 4 shows one example for a semiconductor device 14 that includes an array 120 of SPAD pixels 202 (sometimes referred to herein as image pixels or pixels) arranged in rows and columns. Array 120 may contain, for example, hundreds or thousands of rows and columns of SPAD pixels 202. Each SPAD pixel may be coupled to an analog pulse counter that generates a corresponding pixel voltage based on received photons. Each SPAD pixel may additionally or alternatively be coupled to a time-of-flight to voltage converter circuit. In both types of readout circuits, voltages may be stored on pixel capacitors and may later be scanned in a row-by-row fashion. Control circuitry 124 may be coupled to row control circuitry 126 and image readout circuitry 128 (sometimes referred to as column control circuitry, readout circuitry, processing circuitry, or column decoder circuitry). Row control circuitry 126 may receive row addresses from control circuitry 124 and supply corresponding row control signals to SPAD pixels 202 over row control paths 130. One or more conductive lines such as column lines 132 may be coupled to each column of pixels 202 in array 120. Column lines 132 may be used for reading out image signals from pixels 202 and for supplying bias signals, such as bias currents or bias voltages, to pixels 202. If desired, during pixel readout operations, a pixel row in array 120 may be selected using row control circuitry 126 and image signals generated by image pixels 202 in that pixel row can be read out along column lines 132.

Image readout circuitry 128 may receive image signals, such as analog or digital signals from the SPAD pixels, over column lines 132. Image readout circuitry 128 may include sample-and-hold circuitry for sampling and temporarily storing image signals read out from array 120, amplifier circuitry, analog-to-digital conversion (ADC) circuitry, bias circuitry, column memory, latch circuitry for selectively enabling or disabling the column circuitry, or other circuitry that is coupled to one or more columns of pixels in array 120 for operating pixels 202 and for reading out signals from pixels 122. ADC circuitry in readout circuitry 128 may convert analog pixel values received from array 120 into corresponding digital pixel values (sometimes referred to as digital image data or digital pixel data). Alternatively, ADC circuitry may be incorporated into each SPAD pixel 202. Image readout circuitry 128 may supply digital pixel data to control and processing circuitry 124 and/or image processing and data formatting circuitry 16 (FIG. 1) over path 125 for pixels in one or more pixel columns.

The example of image sensor 14 having readout circuitry to read out signals from the SPAD pixels in a row-by-row manner is merely illustrative. In other embodiments, the readout circuitry in the image sensor may simply include digital pulse counting circuits coupled to each SPAD pixel. Any other desired readout circuitry arrangement may be used.

If desired, array 120 may be part of a stacked-die arrangement in which pixels 202 of array 120 are split between two or more stacked substrates. Alternatively, pixels 202 may be formed in a first substrate and some or all of the corresponding control and readout circuitry may be formed in a second substrate. Each of the pixels 202 in the array 120 may be split between the two dies at any desired node within pixel.

It should be understood that instead of having an array of SPAD pixels as in FIG. 4, SPAD-based semiconductor device 14 may instead have an array of silicon photomultipliers (each of which includes multiple SPAD pixels with a common output), such as is shown in FIG. 2. Moreover, although FIG. 3 shows an imaging system with semiconductor device 14, semiconductor device 14 may be a standalone device, such as the SiPM device of FIG. 2.

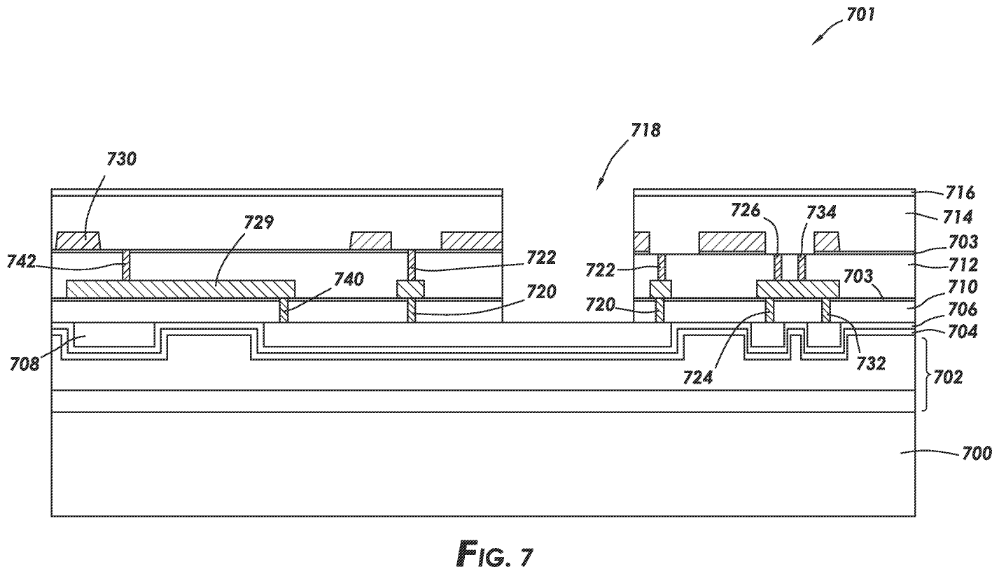

Regardless of the layout of semiconductor device 14, the use of SPADs may require large photosensitive regions to allow the SPADs to effectively sense incident light. Additionally, the larger size of semiconductor device 14 may require higher voltages than other devices, such as at least 15V, at least 20V, 30V, or other desired voltage. The higher voltage of semiconductor device 14 may lead to higher amounts of water and moisture ingress into semiconductor device 14. Therefore, semiconductor device 14 may be provided with sealing structures to prevent or reduce water and/or moisture ingress. Illustrative examples of semiconductor devices having sealing structures to prevent water/moisture ingress are shown in FIGS. 5-12.

As shown in FIG. 5, semiconductor device 501, which may be used as semiconductor device 14 of FIG. 3 or as a standalone semiconductor device, may be a backside SPAD device that includes silicon layer 500, internal circuitry layer 502, silicon nitride and silicon oxide layers 504 and 506, and overlapping metal and dielectric layers. In particular, the overlapping metal and dielectric layers may include second metal layer 508, second dielectric layer 510, first metal layer 529, first dielectric layer 512, shallow trench isolation layer 530, substrate 514, and lower layer 516. Through silicon via (TSV) 518 may be formed through substrate 514 and dielectric layers 510 and 512.

Generally, without any additional protection, water/moisture may be able to enter semiconductor device 501 through TSV 518. To reduce or prevent the risk of moisture entering through TSV 518, through silicon via (TSV) seal rings 520 and 522 may surround TSV 518. TSV seal ring 522 may extend from substrate 514 to first metal layer 529. TSV seal ring 520 may extend from first metal layer 529 to second metal layer 508. As shown in FIG. 5, TSV seal ring 522 may be coupled to a first portion of first metal layer 529, while TSV seal ring 520 may be coupled to a second portion of first metal layer 529. The first and second portions of first metal layer 529 may be offset from each other. TSV seal rings 520 and 522 may form concentric rings, such as circular rings, square rings, rectangular rings, or rings of other desired shapes, around TSV 518.

To protect semiconductor device 14 from ingress between the offset portions of first metal layer 529, barrier layers 503 may be included between dielectric layers 510 and 512, and between dielectric layer 512 and substrate 514, if desired. As shown in FIG. 5, barrier layers 503 may extend across the offset between the offset portions of first metal layer 529 (and/or entirely across layers 510, 512, and 514) and may therefore reduce or prevent water ingress into semiconductor device 14 through the offset region. Barrier layers 503 may be formed from silicon nitride, or another desired material to prevent or reduce water/moisture ingress.

Vias 526 and 534 may extend from substrate 514 to first metal layer 529 at an edge portion of substrate 514. Similarly, vias 524 and 532 may extend from first metal layer 529 to second metal layer 508 at the edge portion of substrate 514. Together, vias 526, 534, 524, and 532 may form a die seal ring at the edge of substrate 514. The die seal ring may run around a periphery of the entire die (e.g., the periphery of semiconductor device 14) to seal the edge of the die.

Vias 540 and 542 may couple second metal layer 508 to first metal layer 529, and first metal layer 529 to substrate 514, respectively.

Dielectric layers 510 and 512 may be formed from any desired dielectric material, such as silicon nitride or silicon oxide.

TSV seal rings 520 and 524, and die seal rings formed from vias 526, 534, 524, and 532, may be formed from tantalum, tantalum nitride, titanium, titanium nitride, or any other desired material. TSV 518 may be formed with tungsten, cobalt, copper, aluminum, or other desired metal.

Metal layers 529 and 508 may be formed from any desired metal, such as copper, aluminum, or tungsten. Second metal layer 508 may form a bond pad, such as a cathode bond pad, to which TSV seal ring 520 is grounded. In particular, the cathode bond pad may have a voltage of at least 15V, at least 20V, 30V, or other desired voltage. In some illustrative embodiments, second metal layer 508 may form a 30V cathode bond pad. The relatively high voltage as compared with non-SPAD devices may allow the larger SPAD devices to function properly.

Because TSV seal ring 520 is coupled between a high-voltage cathode bond pad and first metal layer 529, the offset between TSV seal ring 520 and TSV seal ring 522, which is created by connecting the seal rings to different portions of first metal layer 529, may reduce leakage and parasitic effects that would otherwise occur. In particular, because TSV seal ring 522 is coupled between first metal layer 529 and substrate 514, which has 0V, coupling TSV seal ring 522 to the same portion of first metal layer 529 as TSV seal ring 520 could lead to undesirable leakage and parasitic effects. By offsetting the two portions of the first metal layer and therefore the TSV seal rings, the performance of semiconductor device 501 may be improved.

Although FIG. 5 shows semiconductor device 14 having separate TSV seal rings and die seal rings, this is merely illustrative. In some embodiments, a semiconductor device may have merged TSV seal rings and die seal rings. An illustrative example of a semiconductor device having merged TSV and die seal rings is shown in FIG. 6.

As shown in FIG. 6, semiconductor device 601, which may be used as semiconductor device 14 of FIG. 3 or as a standalone semiconductor device, may generally have the same layout as the semiconductor device of FIG. 5. In particular, semiconductor device 601 may be a backside SPAD device that includes silicon layer 600, internal circuitry layer 602, silicon nitride and silicon oxide layers 604 and 606, second metal layer 608 (having a portion forming a cathode bond pad), second dielectric layer 610, first metal layer 629, first dielectric layer 612, barrier layers 603, shallow trench isolation layer 630, vias 640 and 642, substrate 614, and lower layer 616 (which may correspond with and be formed from the same materials as the corresponding components of FIG. 5, if desired). Through silicon via (TSV) 618 may be formed through substrate 614 and dielectric layers 610 and 612.

TSV seal rings 620 and 622 (which may correspond to TSV seal rings 520 and 522 of FIG. 5) may be merged with die seal rings that protect the edge of the die a at a periphery of substrate 612. In other words, seal rings 620 and 622 may form both TSV seal rings (concentric seal rings around TSV 618) and die seal rings (seal rings at the edge of the die). In this way, semiconductor device 601 may be protected from ingress at TSV 618 and from the edge of the die, while reducing the lateral footprint relative to the semiconductor device of FIG. 5.

Vias 632 and 626 may form additional portions of a die seal ring, if desired.

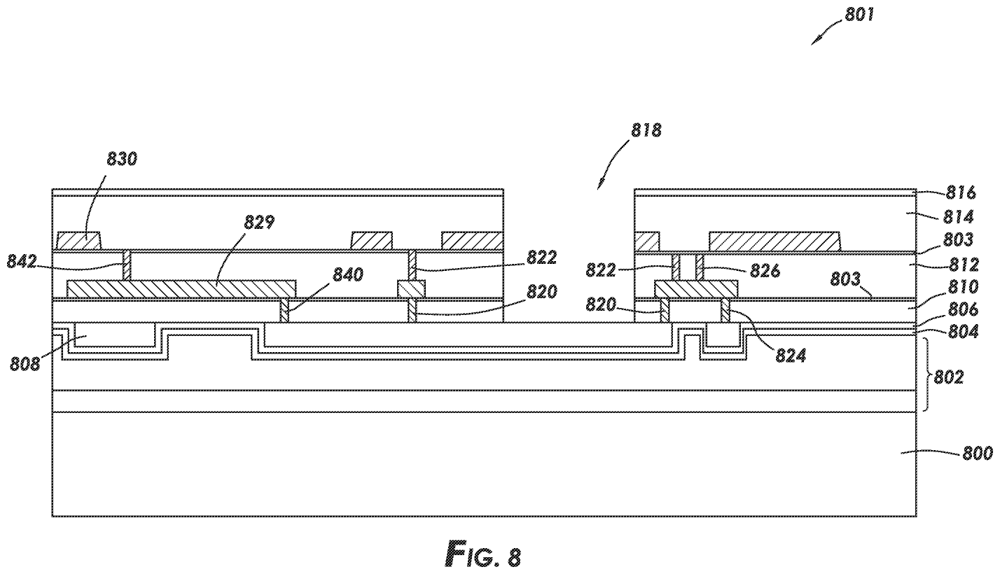

The second metal layer (layer 508 in FIG. 5 and layer 608 in FIG. 6) has been described as having portions that form cathode bond pads. Additionally or alternatively, the second metal layer may have portions that form anode bond pads. As opposed to the cathode bond pads that have a high voltage, the anode bond pads may have a low voltage or 0V. TSV seal rings may be grounded to the anode bond pads. An illustrative example of a semiconductor device having TSV seal rings grounded to an anode bond pad is shown in FIG. 7.

As shown in FIG. 7, semiconductor device 701, which may be used as semiconductor device 14 of FIG. 3 or as a standalone semiconductor device, may generally have the same layout as the semiconductor device of FIGS. 5 and 6. In particular, semiconductor device 14 may be a backside SPAD device that includes silicon layer 700, internal circuitry layer 702, silicon nitride and silicon oxide layers 704 and 706, second metal layer 708, second dielectric layer 710, first metal layer 729, first dielectric layer 712, barrier layers 703, shallow trench isolation layer 730, vias 740 and 742, substrate 714, and lower layer 716 (which may correspond with and be formed from the same materials as the corresponding components of FIGS. 5 and 6, if desired). Through silicon via (TSV) 718 may be formed through substrate 714 and dielectric layers 710 and 712.

Second metal layer 708 may have a portion that forms an anode bond pad. The anode bond pad may be a 0V anode bond pad, for example. TSV seal rings 720 and 722 may surround TSV 718. In particular, TSV seal ring 720 may extend from an anode bond pad formed by a portion of second metal layer 708 to a portion of first metal layer 729. In other words, TSV seal ring 720 may be grounded to the anode bond pad. TSV seal ring 722 may extend from the same portion of first metal layer 729 to substrate 714. Because TSV seal ring 720 is grounded to a 0V anode bond pad formed by second metal layer 708, TSV seal ring 722 may be coupled to the same portion of first metal layer 729 and to substrate 714, which is also at 0V, without parasitic losses and/or leakage that would occur if TSV seal ring 720 were grounded to a higher voltage, such as when coupled to a higher voltage cathode bond pad in FIGS. 5 and 6. By coupling TSV sealing rings 720 and 722 to the same portion of first metal layer 729, layout space may be saved by reducing the lateral layout of semiconductor device 14, and manufacturing may be simplified, as an additional portion of first metal layer 729 may not need to be deposited.

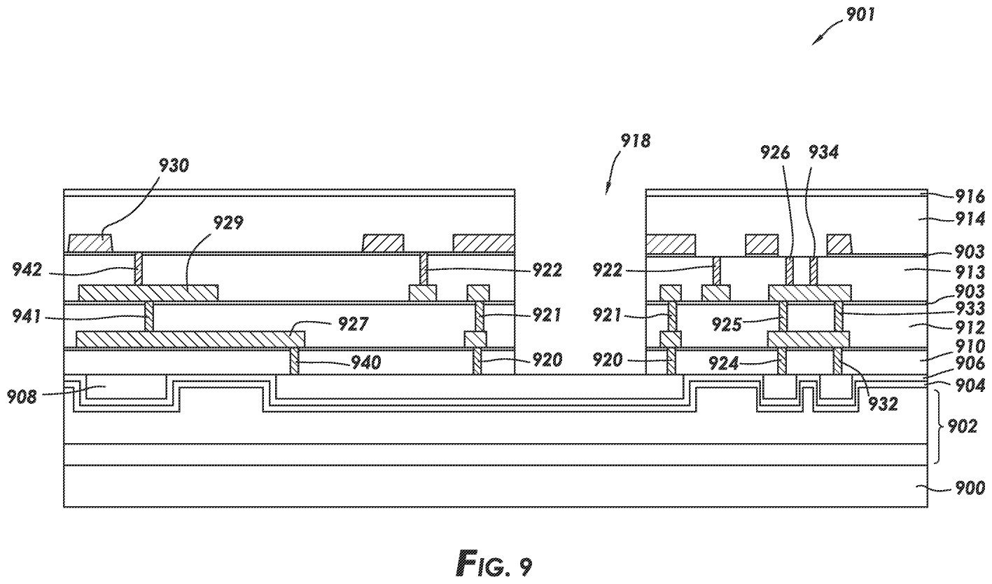

In the example of FIG. 7, semiconductor device 701 has a separate die seal ring (formed from vias 726, 734, 724, and 732) at an edge of substrate 714. As with the die seal in FIG. 5, the die seal may run around a periphery of the entire die (e.g., the periphery of semiconductor device 14) to seal the edge of the die. However, this is merely illustrative. If desired, a semiconductor device having a TSV seal ring grounded to an anode bond pad may be merged with a die seal ring. An example of an illustrative semiconductor device having a TSV and die seal ring grounded to an anode bond pad is shown in FIG. 8.

As shown in FIG. 8, semiconductor device 801, which may be used as semiconductor device 14 of FIG. 3 or as a standalone semiconductor device, may generally have the same layout as the semiconductor device of FIG. 7. In particular, semiconductor device 801 may be a backside SPAD device that includes silicon layer 800, internal circuitry layer 802, silicon nitride and silicon oxide layers 804 and 806, second metal layer 808 (having a portion forming an anode bond pad), second dielectric layer 810, first metal layer 829, first dielectric layer 812, barrier layers 803, shallow trench isolation layer 830, vias 840 and 842, substrate 814, and lower layer 816 (which may correspond with and be formed from the same materials as the corresponding components of FIG. 7, if desired). Through silicon via (TSV) 818 may be formed through substrate 814 and dielectric layers 810 and 812.

TSV seal rings 820 and 822 (which may correspond to TSV seal rings 720 and 722 of FIG. 7) may be merged with die seal rings that protect the edge of substrate 812. In other words, seal rings 820 and 822 may form both TSV seal rings (concentric seal rings around TSV 818) and die seal rings (seal rings at the edge of substrate 814). Because seal ring 820 is grounded to a 0V anode bond pad, the portion of seal ring 820 that forms both a TSV seal ring and a die seal may be coupled directly to the anode bond pad. Vias 824 and 826 may form an additional portion of the die seal, if desired. In this way, semiconductor device 14 may be protected from ingress at TSV 818 and from the edge of the die, while reducing the lateral footprint relative to the semiconductor device of FIG. 7.

Vias 824 and 826 may form additional portions of a die seal, if desired.

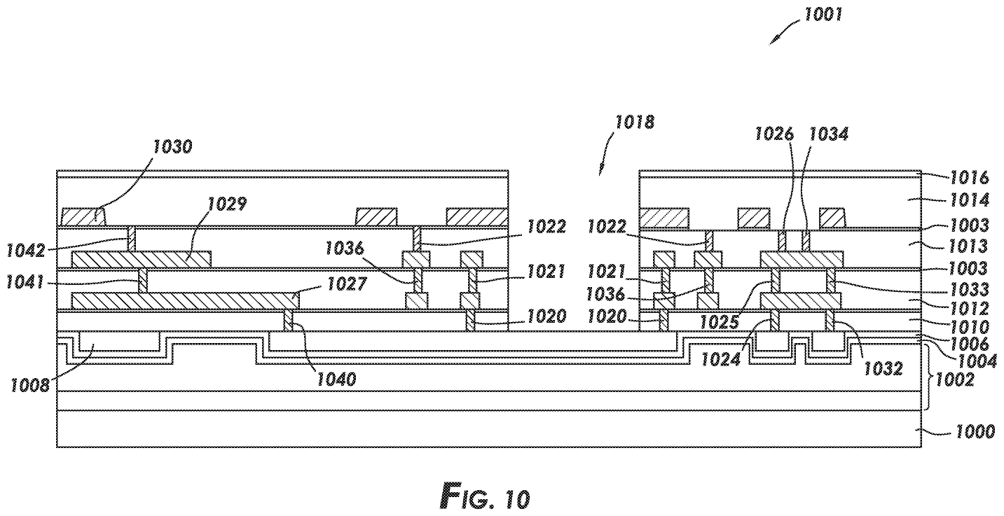

FIGS. 5-8 show TSV seal rings in semiconductor devices (or semiconductor device portions) having two metal layers and two dielectric layers. However, this is merely illustrative. In general, the TSV seal rings (and optionally the merged die seal rings) of FIGS. 5-8 may be included in a semiconductor device or semiconductor device portion with any desired number of metal layers and/or dielectric layers. Illustrative examples of semiconductor devices or semiconductor device portions having three metal layers and dielectric layers are shown in FIGS. 9-12.

As shown in FIG. 9, semiconductor device 901, which may be used as semiconductor device 14 of FIG. 3 or as a standalone semiconductor device, may generally have the same layout as the semiconductor device of FIG. 5, with the addition of an additional dielectric layer and metal layer. In particular, semiconductor device 901 may be a backside SPAD device that includes silicon layer 900, internal circuitry layer 902, silicon nitride and silicon oxide layers 904 and 906, third metal layer 908 (having a portion forming a cathode bond pad), third dielectric layer 910, second metal layer 927, second dielectric layer 912, first metal layer 929, first dielectric layer 913, barrier layers 903, shallow trench isolation layer 930, vias 940, 941, and 942, substrate 914, and lower layer 916 (which may correspond with and be formed from the same materials as the corresponding components of FIG. 5, if desired). Through silicon via (TSV) 918 may be formed through substrate 914 and dielectric layers 910, 912, and 913. A die seal may be formed from vias 926, 934, 925, 933, 924, and 932.

TSV seal ring 920 may be coupled between the cathode bond pad of third metal layer 908 and second metal layer 921. TSV seal ring 921 may be coupled between first metal layer 929 and second metal layer 927. TSV seal ring 922 may be coupled between first metal layer 929 and substrate 914.

As with the arrangement of FIG. 5, TSV seal ring 922 may be coupled to a different portion of first metal layer 929 than TSV seal ring 921. In other words, TSV seal ring 922 may be coupled to a first portion of first metal layer 929, while TSV seal ring 921 may be coupled to a second portion of first metal layer 929 that is laterally offset from the first portion. Because the cathode bond pad may have a high voltage, such as 30V, and substrate 914 may have a low voltage, such as 0V, having TSV seal rings 921 and 922 coupled to offset portions of first metal layer 929 may prevent or reduce parasitic losses or leakage.

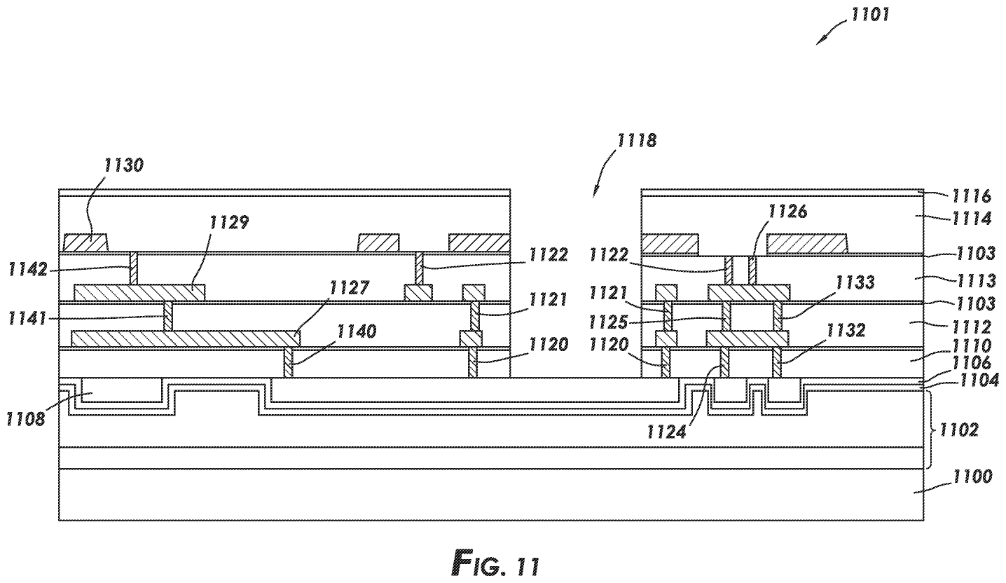

If desired, an additional seal ring may be formed between the first metal layer and the second metal layer. An illustrative example of an additional seal ring between the first and second metal layers is shown in FIG. 10.

Semiconductor device 10001 of FIG. 10, which may be used as semiconductor device 14 of FIG. 3 or as a standalone semiconductor device, may have the same layout as the device or portion of FIG. 9, with the addition of seal ring 1036 between first metal layer 1029 and second metal layer 1027 (which may correspond with first metal layer 929 and second metal layer 927 of FIG. 9, respectively). The addition of seal ring 1036 may provide additional protection from ingress. Moreover, because seal ring 1036 and seal ring 1021 are coupled to different portions of first metal layer 1029 and second metal layer 1027, the cathode bond pad formed by third metal layer 1008 will not be shorted to substrate 1014. In this way, seal ring 1026 may provide additional protection for the semiconductor device without increasing parasitic effects or leakage.

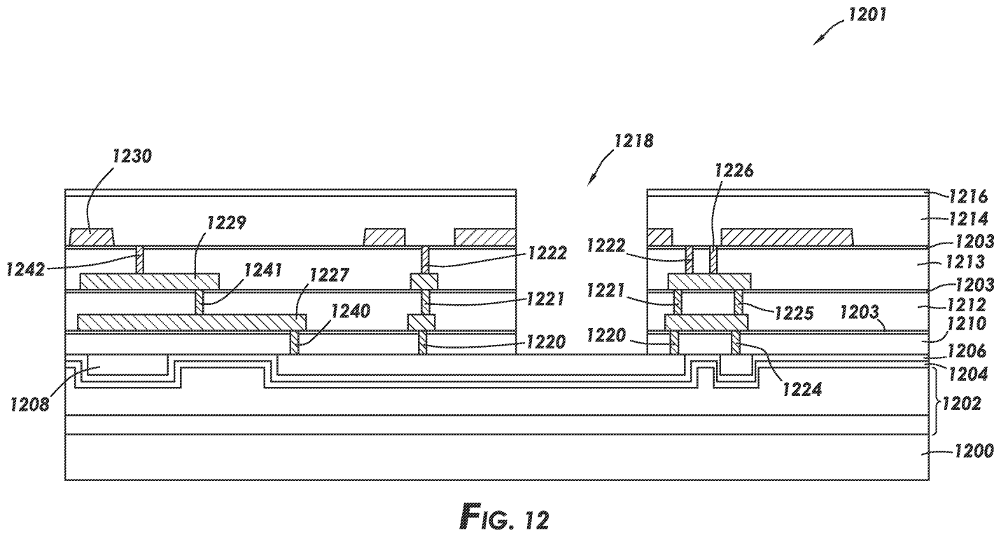

Alternatively or additionally to adding an additional seal ring between the first metal layer and the second metal layer, the TSV seal rings may be merged with the die seal. An illustrative example of a three-layered semiconductor device portion having merged TSV seal rings coupled to a cathode bond pad and merged with a die seal ring is shown in FIG. 11.

As shown in FIG. 11, semiconductor device 1101, which may be used as semiconductor device 14 of FIG. 3 or as a standalone semiconductor device, may generally have the same layout as the semiconductor device of FIGS. 9 and 10. In particular, semiconductor device 1101 may be a backside SPAD device that includes silicon layer 1100, internal circuitry layer 1102, silicon nitride and silicon oxide layers 1104 and 1106, third metal layer 1108 (having a portion forming a cathode bond pad), third dielectric layer 1110, second metal layer 1127, second dielectric layer 1112, first metal layer 1129, first dielectric layer 1113, barrier layers 1103, shallow trench isolation layer 1130, substrate 1114, vias 1140, 1141, and 1142, and lower layer 1116 (which may correspond with and be formed from the same materials as the corresponding components of FIGS. 9 and 10, if desired). Through silicon via (TSV) 1118 may be formed through substrate 1114 and dielectric layers 1110 and 1112.

TSV seal rings 1120, 1121, and 1122 (which may correspond to TSV seal rings 920, 921, and 922 of FIG. 9) may be merged with die seal rings that protect the edge of the die. In other words, seal rings 1120, 1121, and 1122 may form both TSV seal rings (concentric seal rings around TSV 1118) and die seal rings (seal rings at the edge of the die around a periphery of substrate 1114). In this way, semiconductor device 1101 may be protected from ingress at TSV 1118 and from the edge of the die, while reducing the lateral footprint relative to the semiconductor device of FIGS. 9 and 10.

The third metal layer (layer 908, 1008, and 1108 in FIGS. 9, 10, and 11, respectively) has been described as having portions that form cathode bond pads. Additionally or alternatively, the third metal layer may have portions that form anode bond pads. As opposed to the cathode bond pads that have a high voltage, the anode bond pads may have a low voltage or 0V. TSV seal rings may be grounded to the anode bond pads. An illustrative example of a semiconductor device having TSV seal rings grounded to an anode bond pad is shown in FIG. 12.

As shown in FIG. 12, semiconductor device 1201, which may be used as semiconductor device 14 of FIG. 3, may generally have the same layout as the semiconductor device of FIGS. 10-11. In particular, semiconductor device 1201 may be a backside SPAD device that includes silicon layer 1200, internal circuitry layer 1202, silicon nitride and silicon oxide layers 1204 and 1206, third metal layer 1208, third dielectric layer 1210, second metal layer 1227, second dielectric layer 1212, first metal layer 1229, first dielectric layer 1213, barrier layers 1203, shallow trench isolation layer 1230, vias 1240, 1241, and 1242, substrate 1214, and lower layer 1216 (which may correspond with and be formed from the same materials as the corresponding components of FIGS. 9-11, if desired). Through silicon via (TSV) 1218 may be formed through substrate 1214 and dielectric layers 1210 and 1212.

Third metal layer 1208 may have a portion that forms an anode bond pad. The anode bond pad may be a 0V anode bond pad, for example. TSV seal rings 1220, 1221, and 1222 may surround TSV 1218. In particular, TSV seal ring 1220 may extend from an anode bond pad formed by a portion of third metal layer 1208 (e.g., may be grounded to the anode bond pad) to a portion of second metal layer 1227. TSV seal ring 1221 may extend from the same portion of the second metal layer 1227 to a portion of first metal layer 1229. TSV seal ring 1222 may extend from the same portion of first metal layer 1229 to substrate 1214. Because TSV seal ring 1220 is grounded to a 0V anode bond pad formed by third metal layer 1208, TSV seal ring 1221 may be coupled to the same portion of second metal layer 1227, which in turn may be coupled to TSV seal ring 1222 through first metal layer 1229 and to substrate 714, which is also at 0V, without parasitic losses and/or leakage that would occur if TSV seal ring 1220 were grounded to a higher voltage, such as when coupled to a higher voltage cathode bond pad in FIGS. 9-11. By coupling TSV sealing rings 1220, 1221, and 1222 to the same portions of first and second metal layers 1229 and 1227, layout space may be saved by reducing the lateral layout of semiconductor device 14, and manufacturing may be simplified, as an additional portion of first and second metal layer 1229 and 1227 do not need to be deposited.

In the example of FIG. 12, semiconductor device 1201 has merged TSV and die seal rings (formed from vias 1220, 1221, and 1222) at an edge of substrate 1214. However, this is merely illustrative. If desired, a semiconductor device may have a die seal ring separate from TSV seal rings 1220, 1221, and 1222.

The examples of FIGS. 5-12 may be used in combination in the same semiconductor device, or may be used in different semiconductor devices. In some illustrative examples, a single semiconductor device 14 or other semiconductor device, such as a SiPM device, may have one cathode TSV seal ring layout (e.g., as shown in FIG. 5, 6, or 9-11) and one anode TSV seal ring layout (e.g., as shown in FIG. 7, 8, or 12). However, this is merely illustrative. A single semiconductor device may have multiple cathode TSV seal ring layouts and/or multiple anode TSV seal ring layouts, if desired.

The foregoing is merely illustrative of the principles of this invention and various modifications can be made by those skilled in the art. The foregoing embodiments may be implemented individually or in any combination.

What is claimed is:

1. A semiconductor device having a frontside and a backside, comprising:
a substrate at the backside;
dielectric layers on the substrate;
first and second metal layers interleaved with the dielectric layers;
a through silicon via formed in the backside through the substrate and the dielectric layers;
a first through silicon via seal ring that extends between the substrate and the first metal layer; and
a second through silicon via seal ring that extends between the first metal layer and the second metal layer.

2. The semiconductor device of claim 1, wherein the first through silicon via seal ring contacts a first portion of the first metal layer, and the second through silicon via seal ring contacts a second portion of the first metal layer that is offset from the first portion.

3. The semiconductor device of claim 2, further comprising:
a die seal having a first portion that extends from the substrate to the first metal layer and a second portion that extends from the first metal layer to the second metal layer.

4. The semiconductor device of claim 2, wherein the second metal layer is a 30V cathode bond pad, and the second through silicon via seal ring contacts the 30V cathode bond pad.

5. The semiconductor device of claim 2, wherein the first through silicon via seal ring and the second through silicon via seal ring are merged with a die seal at an edge of the substrate.

6. The semiconductor device of claim 2, wherein the second through silicon via seal ring contacts a first portion of the second metal layer, the semiconductor device further comprising:
a third metal layer, wherein the second metal layer is interposed between the first metal layer and the third metal layer;
a third through silicon via seal ring that extends between the first portion of the second metal layer and the third metal layer.

7. The semiconductor device of claim 6, further comprising:
a fourth through silicon via seal ring that extends from the first portion of the first metal layer to a second portion of the second metal layer that is different from the first portion of the second metal layer.

8. The semiconductor device of claim 6, wherein the first through silicon via seal ring, the second through silicon via seal ring, and the third through silicon via seal ring are merged with a die seal at an edge of the substrate.

9. The semiconductor device of claim 1, wherein the first through silicon via seal ring contacts a given portion of the first metal layer, and the second through silicon via seal ring contacts the given portion of the first metal layer.

10. The semiconductor device of claim 9, further comprising:
a die seal having a first portion that extends from the substrate to the first metal layer and a second portion that extends from the first metal layer to the second metal layer.

11. The semiconductor device of claim 9, wherein the first through silicon via seal ring and the second through silicon via seal ring are merged with a die seal at an edge of the substrate.

12. The semiconductor device of claim 9, wherein the second through silicon via seal ring contacts a given portion of the second metal layer, the semiconductor device further comprising:
a third metal layer, wherein the second metal layer is interposed between the first metal layer and the third metal layer;
a third through silicon via seal ring that extends between the given portion of the second metal layer and the third metal layer.

13. The semiconductor device of claim 12, wherein the second metal layer comprises a 0V anode bond pad, and the second through silicon via seal ring contacts the 0V anode bond pad.

14. A semiconductor device, comprising:
a substrate;
a first metal layer;
a second metal layer;
a through silicon via that extends through the substrate to the second metal layer; and
first and second through silicon via seal rings, wherein the first through silicon via seal ring extends from the substrate to a first portion of the first metal layer, and the second through silicon via seal ring extends from the second metal layer to a second portion of the first metal layer that is offset from the first portion.

15. The semiconductor device of claim 14, wherein the second metal layer comprises a 30V cathode bond pad, and wherein the second through silicon via seal ring is coupled to the 30V cathode bond pad.

16. The semiconductor device of claim 15, further comprising:
a barrier layer that extends between the first portion of the first metal layer and the second portion of the first metal layer to cover the offset.

17. The semiconductor device of claim 15, further comprising:
a die seal having a first portion that extends from the substrate to the first metal layer and a second portion that extends from the first metal layer to the second metal layer.

18. The semiconductor device of claim 15, wherein the first and second through silicon via seal rings are merged with a die seal at an edge of the substrate.

19. A semiconductor device, comprising:
a substrate;
a first metal layer;
a second metal layer;
a through silicon via that extends through the substrate to the second metal layer; and
first and second through silicon via seal rings, wherein the first through silicon via seal ring extends from the substrate to a given portion of the first metal layer, the second through silicon via seal ring extends from the given portion of the first metal layer to the second metal layer, and the first and second through silicon via seal rings are merged with a die seal at an edge of the substrate.

20. The semiconductor device of claim 19, wherein the second metal layer comprises a 0V anode bond pad, and wherein the second through silicon via seal ring is coupled to the 0V anode bond pad.
